(19) United States
(12) Patent Application Publication
(10) Pub. No.: US 2017/0092831 A1
(43) Pub. Date: Mar. 30, 2017

(54) MOLECULAR THERMOELECTRIC LIPID BILAYERS AND A DEVICE USING THE SAME

(71) Applicant: Worcester Polytechnic Institute, Worcester, MA (US)

(72) Inventor: Steven Van Dessel, Shrewsbury, MA (US)

(21) Appl. No.: 15/278,201

(22) Filed: Sep. 28, 2016

Related U.S. Application Data
(60) Provisional application No. 62/233,552, filed on Sep. 28, 2015.

(51) Int. Cl. H01L 35/24; H01L 35/32

(52) U.S. Cl. CPC H01L 35/24; H01L 35/32

(57) ABSTRACT

A molecular thermoelectric (M-TE) lipid layer includes a lipid bilayer or monolayer and a dopant, and in particular, the dopant can be an n-type dopant, a p-type dopant, or a hybrid thereof. The dopant can be selected from modified biological molecules, such as lipid, transmembrane protein and oligonucleotides. A molecular thermoelectric (M-TE) lipid device can incorporate the molecular thermoelectric (M-TE) lipid layer.

### BACKGROUND

(a) Technical Field

The present invention relates to a molecular thermoelectric (M-TE) lipid layer and a device using the same. In particular, the molecular thermoelectric lipid layer includes a biological or synthetic lipid bilayer and biological or synthetic molecules used as a dopant to provide a thermoelectric effect.

(b) Description of the Related Art

Thermoelectric (TE) systems convert temperature differences directly into electric power, or vice versa. The underlying TE phenomena are known as the Seebeck effect, the Peltier effect, and the Thompson effect (see, e.g., D. M. Rowe, Thermoelectrics Handbook: Macro to Nano, 2005; David Nemir et al., Journal of Electronic Materials, 2010; Diana Enescu et al., Renewable and Sustainable Energy Reviews, 2014; Dongliang Zhao et al., Applied Thermal Engineering, 2014; Mohamed Hamid Elsheikh et al., Renewable and Sustainable Energy Reviews, 2014; and X. F. Zheng, et al., Renewable and Sustainable Energy Reviews, 2014).

Typically, TE-systems consist of an electrical circuit formed of two dissimilar conductors, referred to as thermoelectric legs, which are connected electrically in series but thermally in parallel (see FIGS. 1A-1B).

For instance, when a current is applied, TE devices operate as solid state heat engines and can be used for various cooling or heating applications. When subject to a thermal gradient, TE devices can generate a current and can thus also be used for power generation. TE systems with a high figure-of-merit (ZT=S2σT/k) requires materials with high thermoelectric power (S), high electrical conductivity (a), and low thermal conductivity (k). Beyond ZT considerations, effective TE systems also require effective heat-transfer at their interfaces to avoid thermal bottlenecks. Most commercial TE systems use n- and p-doped semi-conducting materials (such as bismuth telluride) for their thermoelectric legs (bulk or thin film). The efficiency of current TE systems has been relative poor, and their use has therefore been confined to niche-applications.

Theoretical predictions have shown that low-dimensional TE systems hold significant potential for improving ZT (see, e.g., L. D. Hicks, et al., Phys. Rev. B 47, 12727; and L. D. Hicks, et al., Phys. Rev. B 47, 16631), and their development has therefore received considerable attention. Current device strategies include super-lattices, segmented materials, nano-composites, nano-tubes, and nano-wires (see, e.g., Marisol Martín-González, et al., Renewable and Sustainable Energy Reviews, 2013; and Hilaal Alam, et al., Nano Energy, 2013). The past decades have also seen steady increase in both theoretical and experimental research aimed at increasing our understanding of single-molecule transport phenomena (see, e.g., Fang Chen, et al., Annual Review of Physical Chemistry, 2007; and N. J. Tao, Nature Nanotechnology, 2006). Recently, studies have also reported on the single-molecule TE properties of selected organic molecules (see, e.g., Sriharsha V. Aradhyal et al., Nature Nanotechnology, 2013; B. Wang et al., Carbon, 2005; Pramod Reddy et al., Science, 2007; C. M. Finch, et al., Phys. Rev. B, 2009; Youngsang Kim et al., Nature Nanotechnology, 2014; Yoshihiro Asai, J. Phys.: Condens. Matter; 2013; Neaton J B, Nature Nanotechnology, 2014; Yu-Shen Liu et al., ACS Nano, 2009; and Jonathan R. Widawsky et al., Nano Lett., 2012). Theoretical studies have predicted very high ZT values for such molecular-scale TE (M-TE) devices (see, e.g., Enrique Macia, Nanotechnology 2005; and Enrique Macia, Phys. Rev. B, 2007).

As such, the development of M-TE systems is appealing as such devices may open new frontiers in the development of cost effective energy conversion systems. To date, however, no practical methods for the fabrication of organic M-TE devices exist. The next step forward is therefore to develop new concepts that enable their development.

### SUMMARY

According to the present invention, a molecular thermoelectric (M-TE) lipid layer may include a lipid bilayer and a dopant, and in particular, the dopant is lipid compatible. Further, the dopant may be an n-type dopant, a p-type dopant, or a hybrid thereof.

The lipid layer may be assembled in vitro, and the lipid layer may be in a form of a monolayer, a bilayer, or mixtures thereof. In certain embodiments, the lipid layer may be formed using a lipid selected from the group consisting of: a fatty acid, a phospholipid, a glycolipid and mixtures thereof.

The lipid-compatible dopant may be a lipid, a peptide, oligonucleotides, a synthetic compound or mixtures thereof. For example, the dopant may include archaeal macrocyclic di-ether lipids or archaeal tetra-ether lipids, a transmembrane peptide or a fragment thereof, or poly(dA)-poly(dT) oligonucleotides, poly(dC)-poly(dG) oligonucleotides or mixtures thereof. Further, the dopant may include a photoactive group which is not embedded in the lipid layer.

When the dopant comprises the transmembrane peptide(protein), the transmembrane peptide may include at least one transmembrane domain that is embedded in the lipid layer. In particular embodiments, one or more of the transmembrane domains may be connected via a linker. In addition, the transmembrane peptide may further include photoactive group which is not embedded in the lipid layer.

For example, the transmembrane peptide may include a fragment obtained from a modified pigment protein, a fragment obtained from a modified ion channel, a fragment obtained from a modified rhodopsin.

In certain embodiments, the lipid layer may be formed in multiple layers.

Further provided in the present invention is a molecular thermoelectric (M-TE) device that may include the molecular thermoelectric (M-TE) lipid layer as described herein, and an electrical conductor. The molecular thermoelectric (M-TE) device herein may be a medical/biologic device, an optical device, a microarray, or a cladding system.

The molecular thermoelectric (M-TE) device may further include a conductive layer disposed on an interior surface of at least one of the substrates and/or a boundary layer arranged adjacent to the conductive layer. In particular, the boundary layer is configured to connect the dopant and the conductive layer. The device may further include an electrolyte or alternatively, a non-conductive solution. The device may further include an electric circuit disposed between the substrates, wherein the substrates are positioned parallel to one another.

Other aspects of the invention are disclosed infra.

### BRIEF DESCRIPTION OF THE DRAWINGS

The above and other objects, features and advantages of the present disclosure will be more apparent from the following detailed description taken in conjunction with the accompanying drawings.

FIGS. 1A-1D illustrate exemplary thermoelectric units or modules. FIG. 1A (RELATED ART) shows a bulk TE unit; FIG. 1B (RELATED ART) shows a bulk TE module; FIG. 1C shows an exemplary molecular scale TE unit; and FIG. 1D shows an exemplary molecular scale TE module according to an exemplary embodiment of the present invention.

FIG. 2A illustrates an exemplary molecular thermoelectric module which may include a lipid bilayer and a transmembrane folded protein (polypeptide) according to an exemplary embodiment of the present invention; and FIG. 2B shows an exemplary lipid membrane serving as heat-dissipating matrix for an M-TE module.

FIGS. 3A-3B illustrate exemplary transmembrane proteins for an exemplary M-TE lipid layer module. FIG. 3A is a rhodopsin embedded in the lipid layer; FIG. 3B is an ion channel; FIG. 3C is a light-harvesting complex; and FIG. 3D is a cytochrome b.

FIG. 4 illustrates an exemplary Trans-Membrane Proteins (TMP)/M-TE ion-channel thermal opening and closing mechanism according to an exemplary embodiment of the present invention.

FIG. 5A is a schematic view of a lipid layer cladding system disposed according to an exemplary embodiment of the present invention; and FIG. 5B is a schematic view of an individual M-TE unit of the lipid layer cladding system of FIG. 5A.

FIG. 6A is a schematic view of Model System 1 (TMP/M-TE) according to an exemplary embodiment of the present invention; and FIG. 6B illustrates an exemplary serial TMP dopant of the Model System 1.

FIG. 7A is a schematic view of Model System 2 (TMP/M-TE) according to an exemplary embodiment of the present invention; and FIG. 7B illustrates an exemplary serial TMP dopant of the Model System 2.

FIGS. 8A-8C illustrates simplified FE model of a nano-scale M-TE unit. FIG. 8A indicates a heat flow; FIG. 8B illustrates a lipid bilayer with a dopant with parameters of thickness or width of each lipid molecule and bilayer; and FIG. 8C illustrates temperature difference formed in the lipid layer of the M-TE system.

FIG. 9A is a schematic view of an exemplary lipid layer cladding system disposed according to an exemplary embodiment of the present invention; FIG. 9B is a schematic view of an individual M-TE unit of the lipid layer cladding system of FIG. 9A.

FIG. 10A is a schematic view of an exemplary solar-powered M-TE lipid cladding system according to an exemplary embodiment of the present invention; and FIG. 10B is a schematic view of an exemplary M-TE dopant of FIG. 10A.

FIG. 11A is a schematic view of a testing method according to the present invention; and FIG. 11B is a schematic view of an alternative dual lipid membrane testing method according to an exemplary embodiment of the present invention.

FIG. 12A shows a planar Patch Clamp device (Nanion® Port-a-Patch™); FIG. 12B illustrates exemplary planar patch clamp mechanisms and recording configurations (b1), (b2), (b3), and FIG. 12C shows a Thermal controller (Nanion®).

FIG. 13A illustrates an exemplary schematic experimental setting; and FIG. 13B (not drawn to scale) shows an enlarged view of a cell-attached patch from FIG. 13A.

FIG. 14 shows an exemplary Supported Lipid Bilayers/Patch Clamp screening of dopants (not drawn to scale) of Example 8 according to an exemplary embodiment of the present invention.

FIG. 15A shows an exemplary M-TE Micro-Module in 3D-cutaway view; and FIG. 15B shows an exemplary M-TE Micro-Module in 2D-diagram (not drawn to scale).

FIG. 16A shows Pilkington-Spatia™ vacuum cladding system of Example 9 according to an exemplary embodiment of the present invention; and FIG. 16B shows an exemplary zero-energy Vacuum Cladding system with M-TE micro-pillars (not drawn to scale) of Example 9 according to an exemplary embodiment of the present invention.

### DETAILED DESCRIPTION

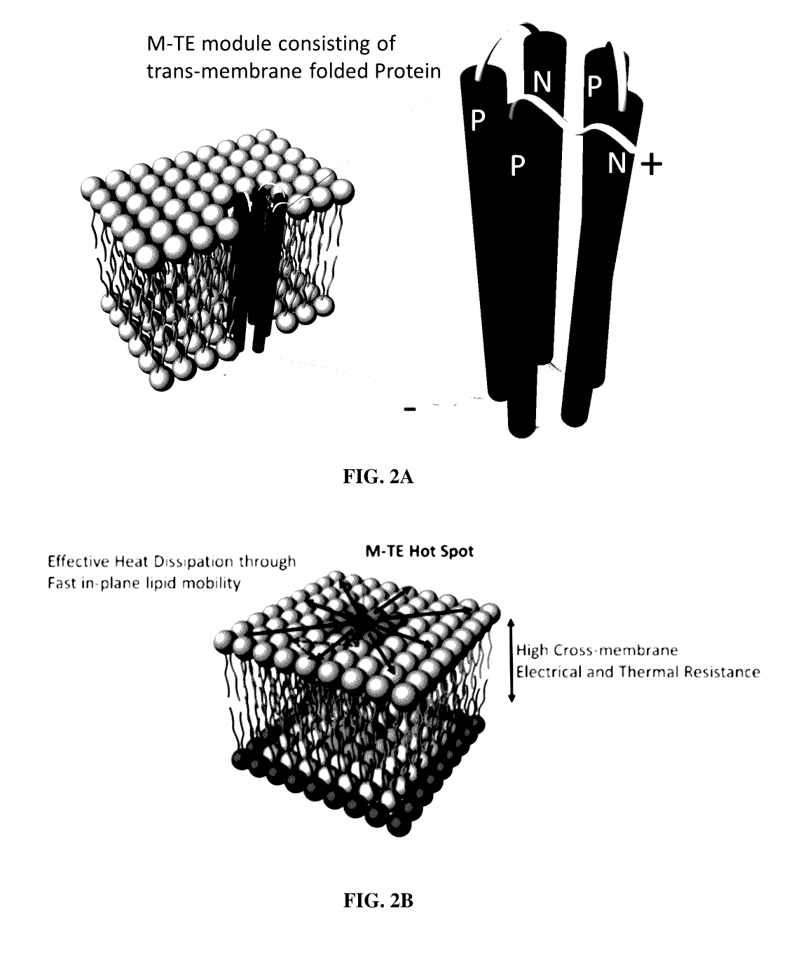

The fabrication of M-TE systems requires molecular self-assembly to attain a functional mesoscale device. While the building blocks of M-TE systems differ significantly from those found in bulk devices, their overall system-architecture can be very similar. Hence, M-TE systems include: (i) molecular TE legs (n and p-type), (ii) molecular wires, (iii) an energy source, and (iv) a heat dissipation systems (see FIG. 2B). Similar to bulk devices, M-TE modules may be constructed by connecting n and p-type molecular units together in series and fold them properly to transfer heat in parallel fashion (see FIG. 2B)

In one aspect, the present invention provides a molecular thermoelectric (M-TE) system which may include a lipid and a dopant embedded in the lipid. In particular, the lipid may be naturally or spontaneously self-assembled into a monolayered or bilayered system to form a planar matrix in aqueous or polar environment. In particular, various lipid compatible molecules, e.g. trans-membrane functional proteins, may be embedded or penetrate thus formed lipid layers, e.g. sheet-like (planar) monolayer or bilayer, thereby constructing a M-TE structure or a M-TE system (see FIGS. 2A-2B).

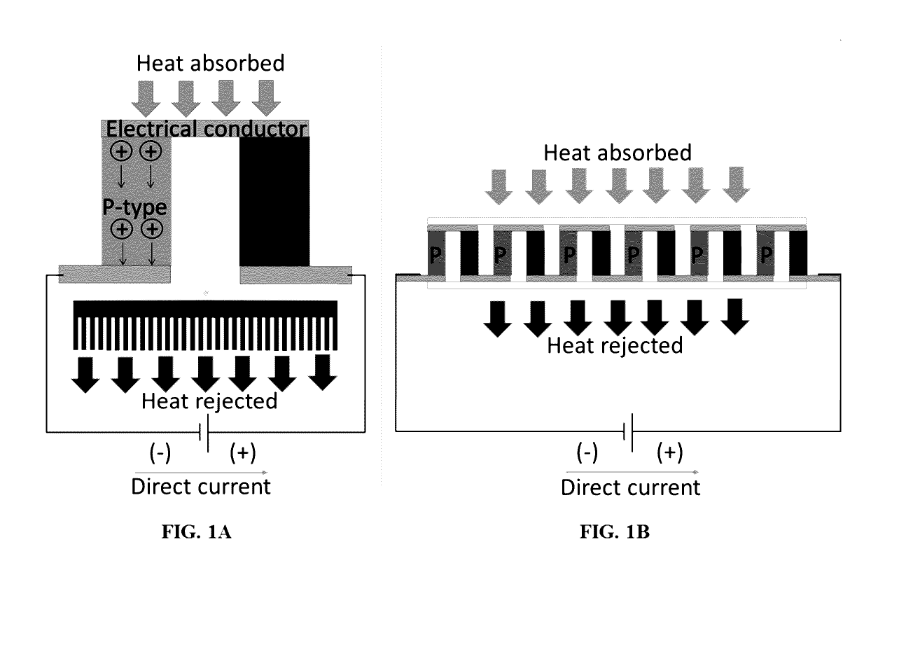

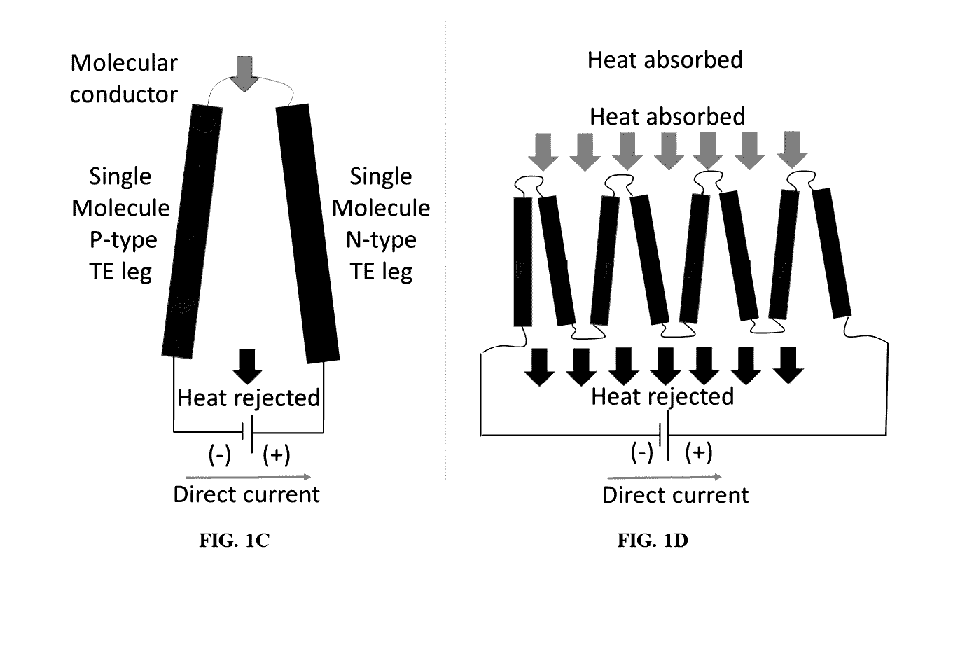

Accordingly, the present invention is based, at least in part, on fabrication of the molecular thermoelectric (M-TE) lipid layer that may be formed in a self-assembled lipid bi-layer. In particular, the molecular thermoelectric (M-TE) lipid layer may be doped with a dopant, i.e. molecular conductor, to create voltage or electrical potential from temperature differences (thermoelectric effect, see FIGS. 1C-1D). Preferably, the dopant may be a p-type dopant, an n-type dopant, or a hybrid thereof, which may be suitably designed, modified or engineered to promote thermoelectric effect in the lipid bilayer, for example, in the M-TE systems.

Further, in another aspect, the present invention provides a molecular thermoelectric (M-TE) device, which may include medical/biologic devices, optical devices, microarrays, window cladding systems and the like, but examples of the devices may not be limited thereto. The M-TE devices, in particular, may apply thermoelectric effects driven by temperature differences to generate electric voltage and operation using the electric power. For instance, the cladding system using the M-TE lipid layer may provide a solar powered cladding system capable of counteracting conductive thermal heat losses or gains occurring through a window. As a result of the invention, a significant reduction in cost and scale as well as reduction in power density of the cladding system can be obtained.

In addition, the present invention may provide a method of measuring electrochemical properties of M-TE system, which is particularly made of the lipid bilayer. As such, the M-TE system comprising the lipid may be suitably used or evaluated for various devices. In preferred aspects, the M-TE system may have (a) good cross-membrane electrical insulation, (b) effective in-plane heat dissipation through fast in-plane lipid mobility, and (c) good cross-plane thermal insulation properties (see FIG. 2B). For instance, the natural ability of lipid bilayers to dissipate heat rapidly across their opposing leaflets allows for the avoidance of thermal bottlenecks, which is an essential design requirement for high performance of the molecular TE system and M-TE devices.

The terminology used herein is for the purpose of describing particular embodiments only and is not intended to be limiting of the invention. As used herein, the singular forms “a,” an and the are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit,” “-er,” “-or,” and “module” described in the specification mean units for processing at least one function and operation, and can be implemented by hardware components or software components and combinations thereof.

Unless specifically stated or obvious from context, as used herein, the term “about” is understood as within a range of normal tolerance in the art, for example within 2 standard deviations of the mean. About can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

### Definitions

The term “hydrophobic group,” as used herein, refers to a nonpolar chemical group or moiety that avoids contact with water or polar solvent. The hydrophobic group interacts with other hydrophobic groups by hydrophobic interaction while the hydrophobic groups is immiscible with water, aqueous solution and polar solution, such that molecules containing at least one or more of the hydrophobic group may aggregate into a certain form, such as micelles, lipid bilayer, liposome, and the like.

The term “hydrophilic group,” as used herein, refers to a polar group that can particularly interact with water or a polar solvent. The hydrophilic group may have atoms that can make a hydrogen bond, dipole interaction or ionic interaction with water molecules. Exemplary hydrophilic group may include hydroxyl groups, carbonyl groups, carboxyl groups, amino groups, sulfhydryl groups, phosphate groups, ethers, esters, phosphodiester group, sugar, carbohydrate, amide group, peptide, metal ions, and the like, which examples may not be limited thereto.

The term “lipid,” as used herein, refers to a naturally occurring molecule encompassing fats, waxes, sterols, fat-soluble vitamins, monoglycerides, diglycerides, triglycerides, phospholipids, and the like. In particular, the lipid molecule includes at least one or more of hydrophobic group which may prevent the lipid from being miscible with water or aqueous environment. As such, the lipid may form a certain structure, such as micelles, lipid bilayer, liposome, and the like.

The term “lipid bi-layer,” as used herein, refers to a structure composed of two-planar layers of lipids. In particular, the lipid molecules in the bilayer includes a hydrophobic group (tail) and a hydrophilic group (head) such that the lipid molecules in aqueous environments can arrange in a double-layered sheet spontaneously formed by hydrophobic interactions between the hydrophobic groups and hydrogen bonding or ionic interactions between the hydrophilic groups, without particular limitations in assembly conditions.

The term “lipid bi-layer” as used herein can also refer to structures composed of a single layer of tetraether lipids. These lipids have two hydrophilic heads that are connected by hydrophobic tails, and can form stable liposomes, planar membranes, and nonlamellar lipid assemblies. These lipids are much more thermostable and are therefore of interest to the invention.

The term, “thermoelectric,” as used herein, refers to as being able to directly convert electricity (electric potential) into temperature differences, or temperature differences into electric potential generally by a thermoelectric material. As such, a thermoelectric material, as being connected to a circuit, may create electricity or voltage when there is a different temperature on each side (see FIG. 1A), or alternatively, when a voltage is applied to it, it creates a temperature difference. In certain embodiments, the thermoelectric material may include dopants that generate electron holes (p-type), or emit extra electrons (n-type).

The terms “dopant” or “doping agent,” as used herein, refers to a trace impurity element included in a matrix (e.g., lipid bi-layer) to change or improve matrix properties, such as electrical conductivity, chemical polarity or optical property. In certain embodiments, the dopant may be included as a thermoelectric substance such that the dopant produces extra electrons or create electron holes to generate and control electricity or electric circuit. For example, “p-type dopant” or “p-type molecule,” as used herein, refers to a dopant molecule that may create an electron hole (missing electron) or accept other electrons from a circuit. Further, “n-type dopant” or “n-type molecule,” as used herein, refer to a dopant molecule that may emit extra electrons to be supplied into a circuit.

The term “hybrid,” as used herein, refers to a fused or mixed form of at least two or more distinct molecules or substances. Preferably, the hybrid may maintain structural or functional characteristics from each molecule or substance. For example, a hybrid dopant in the present invention may be formed of at least one or more p-type dopants and at least one or more n-type dopants and each dopant may possess structural or functional characteristics thereof as being connected or fused to each other.

The term “photoactive group,” as used herein, refers to a chemical group that can chemically react in response to light or sunlight and produce a product or an electron, without limitations to the wavelength ranges of the light radiation. In certain embodiments, the photoactive group may include, which may include a chemical moiety, a peptide fragment, or a catalyst.

The term “cladding system,” as used herein, refers to a component applied to a window panel or a substrate thereof (e.g., glass panes, metals, or polymers) in order to provide functional and aesthetic features, e.g., insulation and appearance. In certain embodiments, the cladding system includes at least one or more of substrate panes or plates, and a material disposed on the glass panes.

The term “conductive layer,” as used herein, may be formed of a conductive material which can sense, induce or transfer electricity or heat. The conductive layer may comprise, but not limited to, metals, electrolytes (e.g., solid or liquid electrolyte), superconductors, semiconductors, plasmas, semiconductor, nonmetallic conductor (e.g., graphite and conductive polymers) and biomaterials.

The term, “boundary layer,” as used herein, may be formed of a material that can be used to adhere or bond two adjacent substances, however, does not induce any physical or chemical changes in those adjacent substances. Further, the boundary layer may be formed to provide electrical conductivity and can be made of a polar liquid that allows and retains lipid layer formation. Further, the boundary layer may be formed to provide physical rigidity and structural stability of the adjacent substances.

The recitation of a listing of other chemical groups in any definition of a variable herein includes definitions of that variable as any single group or combination of listed groups. The recitation of an embodiment for a variable or aspect herein includes that embodiment as any single embodiment or in combination with any other embodiments or portions thereof.

Any compositions or methods provided herein can be combined with one or more of any of the other compositions and methods provided herein.

### Molecular Thermoelectric (M-TE) Lipid Layer

In one aspect, according to the present invention, a molecular thermoelectric (M-TE) lipid layer includes a lipid layer and a dopant embedded in the lipid layer. The lipid layer may be made in a form of monolayer, bilayer, a vesicle, a micelle, a bicelle, or the like without limitation. In particular, the lipid layer may have good thermal and electrical insulation properties across the layer or membrane (bilayers) and thus, effectively prevent cross-plane heat dissipation. Further, the lipid bilayer may serve as a matrix which can stabilize the structure of the M-TE lipid layer and other essential molecules for thermoelectric effect. In certain exemplary embodiments, the M-TE lipid layer may be a planar monolayer or a planar bilayer. In certain exemplary embodiment, the planar lipid layer may be provided as a single layer or multiple layers which may be stacked in a substantially parallel manner, without limitations to numbers or thickness thereof. Alternatively, individual lipid layer may be arranged in a different manner, for example, in which the lipid bilayers are arranged at predetermined angles (e.g., perpendicular) to each other.

Each lipid or lipid molecule forming above structures may include a hydrophilic head group and a hydrophobic tail group. The head groups may face toward hydrophilic or aqueous environments, while the tail groups may aggregate and be held together. However, without limiting the types of lipids or lipid molecules that can be used with the present invention, any lipids or lipid molecules which may be self-assembled in the sheet-like (planar) layer can be used without limitation. In particular embodiments, the lipid molecules forming the monolayer or bilayer may be synthetic or naturally existing lipids. As shown in FIG. 2, the lipid molecules containing hydrophilic head groups and hydrophobic tail groups may be aligned in a sheet-like structure, where tail groups may form an inner portion while head groups may form outer portions.

Particularly, the lipid bilayer is naturally seen in a living cell as a basic cell membrane that forms a continuous barrier around the cell. Further, the lipid bilayer may be assembled in vitro using a synthetic lipid, a natural lipid, or mixtures thereof, without being limited to particular types of lipids. Such a lipid bilayer assembled in vitro (model lipid bilayer) may be formed by any techniques generally used in the art, and the model lipid bilayer may be, but is not limited to, black lipid membranes (BLM), supported lipid bilayers (SLB), tethered bilayer lipid membranes (t-BLM), a vesicle, a micelle, a bicelle, a nanodisc and the like. Additionally, the lipid monolayer also exist naturally forming a barrier in particular archaea, extremophiles or the like. Synthetic or modified lipid molecules may be formed in a suitable and stable monolayer form with any techniques generally known in the art.

In certain embodiments, the lipid may include one or more selected from the group of: a fatty acid, and a phospholipid, including but not limited to as phosphatidylcholine, phosphatidylethanolamine, phosphoinositide, phosphatidylserine, and the like, a glycolipid, archaeols, macrocyclic diethers, and tetraether lipids. Preferably, the above lipid may be suitably purified, modified or synthesized to promote formation of the lipid bilayer in vitro.

Each lipid bilayer or monolayer may suitably have a thickness ranging from about 0.1 nm to about 100 nm, from about 0.5 nm to about 50 nm, or from about 1 nm to about 10 nm. Further, when the M-TE lipid layer includes multiple lipid bilayers or monolayers stacked in parallel or substantially in parallel, a total thickness there may be less than about 1 mm, less than about 100 μm, less than about 50 μm, less than about 10 μm, or from about 1 nm to about 100 μm. Alternatively, the M-TE lipid layer may comprise at least 10, at least 20, at least 30, at least 40, at least 50, at least 60, at least 70, at least 80, at least 90 or at least 100 lipid bilayers or monolayers, to provide suitable thickness thereof.

The dopant may be lipid compatible. In other words, the dopant may be inserted or embedded without disrupting the inner portion of the lipid bilayer or stability of the bilayer structure. Further, the dopant may be embedded or penetrate in the lipid bilayers as being oriented substantially perpendicularly with respect to the surface of the lipid bilayers. When the M-TE lipid layer includes the multiple lipid bilayers, the dopant may penetrate the multiple layers, or the dopants from individual lipid bilayers may be interconnected to maintain vertical connectivity.

The lipid compatible dopant may be a naturally existing molecule, such as lipid, protein and nucleic acids, or a modified or engineered molecule thereof. Further, the lipid compatible dopant may be a naturally existing metabolite or a transmembrane biomolecule such as cholesterol, or a synthetic molecule, such as an organic compound, inorganic compound or synthetic biomolecule.

In certain exemplary embodiments, the lipid-compatible dopant may be a lipid-like dopant which may include at least a portion penetrating the hydrophobic inner portion of the lipid bilayer. Such lipid-type dopant can be obtained naturally from any living creature, such as microorganisms, plants, animals, archaea, fungi and the like, or alternatively, can be obtained from a synthetic or modified lipid. Exemplary lipid-like dopant may be archaeal macrocyclic di-ether lipids, archaeal tetra-ether lipids, and the like. Preferably, the lipid-like dopant may serve as a p-type dopant, n-type dopant, or a hybrid thereof.

In certain exemplary embodiment, the lipid-compatible dopant may be a transmembrane polypeptide or fragments thereof that may include at least a portion penetrating the hydrophobic inner portion of the lipid bilayer. Preferably, the TMP and fragments thereof may serve as a p-type dopant, n-type dopant, or a hybrid thereof.

FIG. 2A schematically illustrates an exemplary TMP/M-TE system. Those peptides can be obtained from natural proteins or polypeptide in any living creature, such as microorganism, plants, animals, archaea, fungi and the like, or alternatively, can be obtained by genetically engineered or synthetic polypeptides.

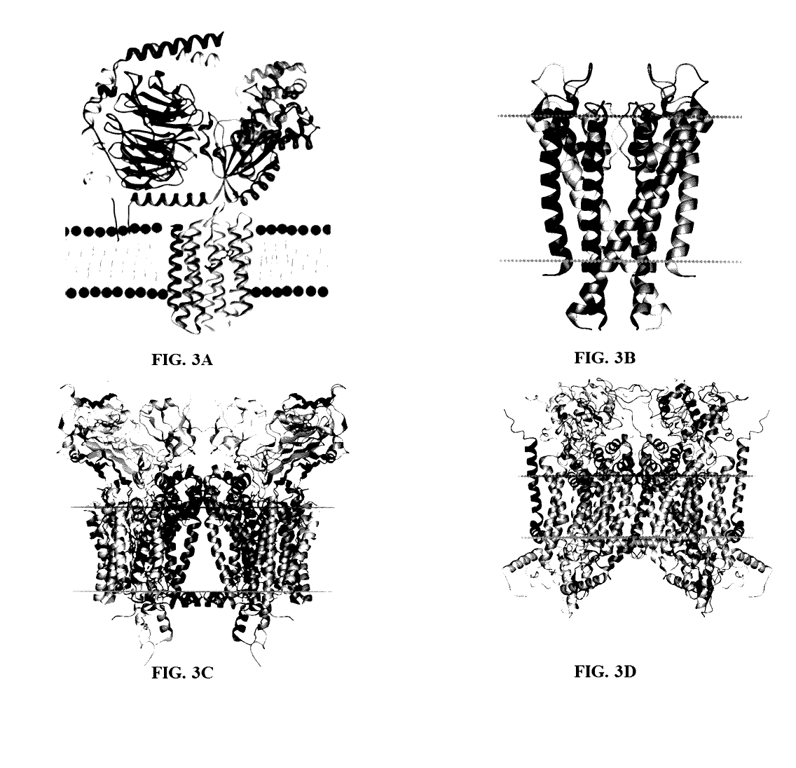

There are many examples of biological trans-membrane proteins (TMP) or polypeptides that may be suitably adopted in an exemplary M-TE system or device as depicted in FIG. 1D. Examples include folded TMP's found in rhodopsin (see FIG. 3A), ion-channels (see FIG. 3B), and pigment-protein subunits of light-harvesting complexes (see FIG. 3C). In addition, a thermostable redox protein cytochrome c may generate electricity with changing temperature, and further, mutated cytochrome c may produce elevated stability and larger temperature dependency. Related TMP, such as cytochrome b, may also be suitably used or adopted for the M-TE system (see FIG. 3D).

In certain embodiments, a pigment or photoactive protein subunits from light-harvesting complexes may include a pair of transmembrane polypeptide-domains which can be embedded in the hydrophobic inner portion of the lipid layers. For example, the pigment-protein found in Rhodopseudomonas may include light harvesting antennas and photosynthetic reaction centers that include complex trans-membrane folded proteins (see FIG. 3C), such that heat difference or thermal gradients generated under sunlight may produce cellular thermoelectric energy conversion as a plausible energy source for such organisms.

In certain exemplary embodiments, the lipid-compatible trans-membrane protein (TMP) dopant may be a modified or chimeric transmembrane polypeptide or fragments thereof. In certain exemplary embodiments, the TMP may include at least one transmembrane domain, at least two transmembrane domains, at least three transmembrane domains, at least four transmembrane domains, or at least five transmembrane domains. In certain embodiments, the transmembrane domain may have a secondary structure, such as □ chain, □-sheet, a channel, and a pore, however the structure may not be limited thereto. In certain exemplary embodiments, each transmembrane domain may be connected or not connected, without limitation. Alternatively, the transmembrane domains may be positioned adjacent to each other, for example, within a distance of about 10 nm, of about 5 nm, or of about 1 nm. In particular embodiments, each transmembrane domain may be linked via chemical group, polymer, or a short peptide so as to substantially maintain parallel structures thereof or to be adjacent within a predetermined distance, thereby enhancing thermoelectric effects. In this case, the length, thickness or shape may not be particularly limited.

In particular embodiments, the transmembrane domain of the above described transmembrane polypeptide dopant may include a pore, a labyrinth, or a channel as an internal structure. Exemplary transmembrane domain may include the entirety of or at least a portion of an ion channel, water channel or small neutral solute channel domain from naturally existing, modified or chimeric polypeptides.

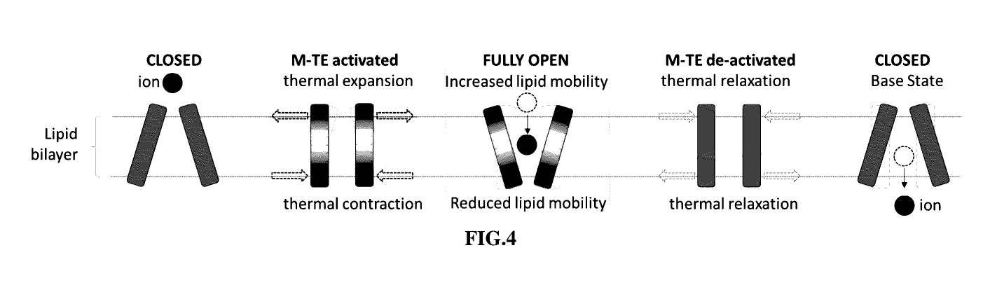

For example, ion-channel domain of the transmembrane polypeptide may provide thermoelectric effect. As illustrated in FIG. 4A, when a potential-difference is applied across a voltage-gated ion-channel that the associated electric-field induces a conformational change in the channel's subunits that distorts their shape sufficiently to allow ions to pass through its inner pore. Additionally, conformational changes may also be induced by a temperature gradient arising across the ion-channel. This localized temperature change may cause ion-channels to alter their shape due to fluidity changes in entire or partial outer regions of the transmembrane polypeptide and adjacent lipids, which can act as an opening and closing mechanism for the channel.

In certain exemplary embodiments, the lipid-compatible dopant may be an oligonucleotide such as RNA, DNA, or modified nucleic acid. Preferably, the oligonucleotides may be controlled by sequence thereof or modified to be lipid compatible in the bilayer structure. For example, the nucleic acids may be synthesized with modified nucleotide to suitably provide hydrophobicity on backbone, but the examples are not limited thereto.

In an exemplary embodiment, poly(dA)-poly(dT) oligonucleotides may act as an efficient n-type dopant.

In particular embodiments, the poly(dA)-poly(dT) oligonucleotides may suitably contain a dA content of greater than about 10%, greater than about 20%, greater than about 30%, greater than about 40%, greater than about 50%, greater than about 60%, greater than about 70%, greater than about 80%, or than about 90%, based on the total nucleotides of the poly(dA)-poly(dT) oligomer (n-type dopant). Alternatively, dT may be suitably included in a content of greater than about 10%, greater than about 20%, greater than about 30%, greater than about 40%, greater than about 50%, greater than about 60%, greater than about 70%, greater than about 80%, or greater than about 90%, based on the total nucleotides of the poly (dA)-poly(dT) oligomer (n-type dopant) Further, the poly(dA)-poly(dT) oligonucleotides may also suitably include other nucleic acids, such as dC, dG, other ribonucleotide, or modified nucleotide, without disrupting the function of the n-type dopant.

In particular embodiments, the poly(dA)-poly(dT) oligonucleotides may be a block copolymer of poly(dA)-poly(dT) or a random copolymer of poly(dA)-poly(dT). Further, a fragment of poly(dA) may occur repeatedly without limitation, suitably at least one time, at least two time, at least three time, at least four time, or at least five time. In addition, a fragment of poly(dT) may occur repeatedly without limitation, suitably at least one time, at least two time, at least three time, at least four time, or at least five time.

In an exemplary embodiment, poly(dC)-poly(dG) oligonucleotides may act as an efficient p-type dopant.

In particular embodiments, the poly(dC)-poly(dG) oligonucleotides may suitably contain a dC content of greater than about 10%, greater than about 20%, greater than about 30%, greater than about 40%, greater than about 50%, greater than about 60%, greater than about 70%, greater than about 80%, or than about 90%, based on the total nucleotides of the poly(dC)-poly(dG) oligomer (p-type dopant). Alternatively, dG may be suitably included in a content of greater than about 10%, greater than about 20%, greater than about 30%, greater than about 40%, greater than about 50%, greater than about 60%, greater than about 70%, greater than about 80%, or greater than about 90%, based on the total nucleotides of the poly (dC)-poly(dG) oligomer (p-type dopant) Further, the poly(dC)-poly(dG) oligonucleotides may also suitably comprise other nucleic acid, such as dA, dT, other ribonucleotide, modified nucleotide, without disrupting the function as of p-type dopant.

In particular embodiments, the poly(dC)-poly(dG) oligonucleotides may be a block copolymer of poly(dC)-poly(dG) or a random copolymer of poly(dC)-poly(dG). Further, a fragment of poly(dC) may occur repeatedly without limitation, suitably at least one time, at least two time, at least three time, at least four time, or at least five time. In addition, a fragment of poly(dG) may occur repeatedly without limitation, suitably at least one time, at least two time, at least three time, at least four time, or at least five time.

In certain exemplary embodiments, the lipid-compatible dopant may be a synthetic molecule that may be embedded in the inner portion of the lipid bilayer without disrupting the structure thereof. Exemplary synthetic dopant may be, but not limited to, biphenyl-4,4′-dithiol and fullerene.

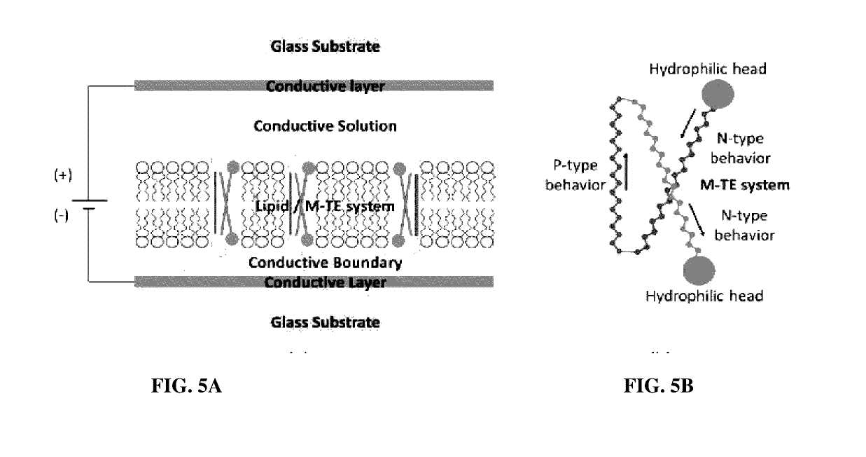

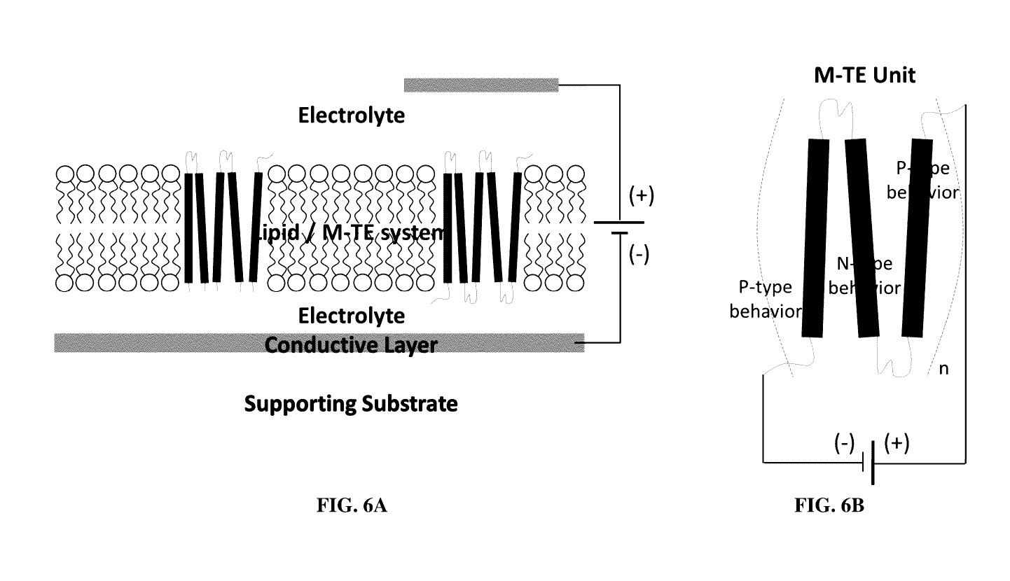

In one preferred embodiment, the dopant may be, each independently, an n-type dopant, p-type dopant, or a hybrid thereof. For instance, the hybrid type dopant may include at least one or more of the n-type dopant moieties and at least one or more of the p-type dopant moieties, however, the number of each dopant moiety may not be limited. In particular, in the hybrid dopant, the dopants may be suitably connected via covalent bond or otherwise using a linker group therebetween the dopant moieties without limitations (see, for example, FIGS. 5A-5B and 6A-6B). As such, chemical groups or length of the linker included in the hybrid molecule may be selected based on the desired number of moieties or design thereof. For example, the linker may include a bent chemical group, such that the dopants may be positioned substantially parallel to each other.

In one preferred embodiment, the TMP dopant may be attached to or modified with a chemical group. For example, the chemical group may stabilize the dopant structure as being embedded in the lipid bilayer. Alternatively, the chemical group may be a hydrophilic group which may assist orientation of the dopant in the lipid bilayer structure. Exemplary hydrophilic chemical group which may be attached on the dopant may include one or more selected from the group of: glyceride, phosphate, sulfate, nitrate, carboxyl, metal ion, metal chelate, amide, carbohydrate, nucleic acid and the like. For example, naturally occurring or modified phosphate glycerol moiety may be attached with ether or ester linkage to the hydrophobic tail to promote spontaneous assembly of the lipid bilayer structure. In addition, for example, the lipid bilayer or monolayer may comprise lipopolysaccharide lipids containing interconnected lipid heads and polysaccharide extensions.

In one preferred embodiment, the dopant may be attached or linked to a photoactive group that may include additional chemical moiety, peptide fragment or catalyst. In certain embodiments, the dopant may be modified to include such chemical moiety, peptide fragment or catalyst toward outside of the lipid bilayer which can generate electrons by excitation in response to light or particularly to sunlight (see, for example, FIG. 3C).

In one preferred aspect, the M-TE lipid layer may include the dopant at a doping ratio that ranges from about 1 wt % to about 50 wt %, from about 5 wt % to about 40 wt %, from about 10 wt % to about 30 wt %, or particularly from about 15 wt % to about 25 wt %, based on the total weight of the M-TE lipid layer.

### A Device Using Molecular Thermoelectric (M-TE) Lipid Layer

In one aspect, according to the present invention, a molecular thermoelectric (M-TE) lipid device may include the M-TE lipid layer as described above.

In certain embodiments, the M-TE device may be included in, but not limited to, a medical/biologic device, a microarray, optical device, or a cladding system.

In certain embodiments, thickness of the various layers, physical properties, lipid/dopant doping ratio, dopant compositions, and geometric design of the M-TE lipid layer may be suitably optimized or varied as being applied in the device without limitation.

In some embodiments, the M-TE lipid layer may be directed or indirectly connected to an electrical conductor such that the conductor may be activated via exposure in response to a direct current or a thermal exposure, thereby forming the device. Further, in another embodiment, the M-TE device including the M-TE lipid layer may be coupled to an external circuit or system.

According to an exemplary embodiment, the molecular thermoelectric (M-TE) lipid device may include a wearable power generator comprising the M-TE lipid layer as described above. The wearable power generator may be used to harness temperature difference between the skin and the ambient, as being embedded therein. Exemplary wearable power generator device may be a watch, clothing, wristband, and the like, however the examples may not be limited thereto. The wearable power generator may also be used to power an electronic device such as a watch, mobile device, smartphone, and the like.

According to an exemplary embodiment, the molecular thermoelectric (M-TE) lipid device may include an implantable power generator that can be implanted under the skin to harness temperature difference between the skin and the ambient. Such implantable power generator device may be used to power, for example, a prosthesis, a pace maker, other medical device, and the like, but the examples may not be limited thereto.

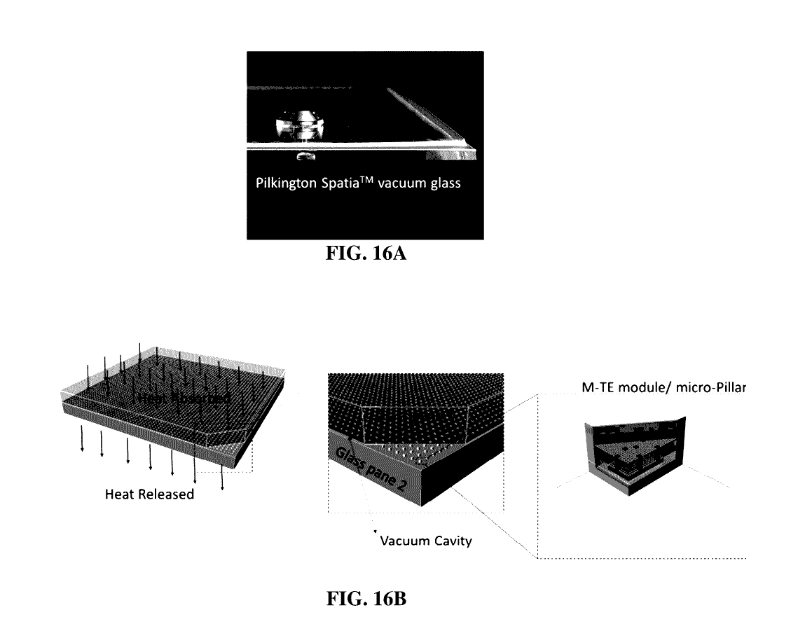

According to an exemplary embodiment, the molecular thermoelectric (M-TE) lipid device may include a cladding system for enclosure thermal control or power generation for a building (FIGS. 16A-16B). The cladding system is provided including a molecular thermoelectric (M-TE) lipid bilayer and substrates. Preferably, the M-TE lipid bilayer may be disposed in the space formed by inner surfaces of at least a pair of the substrates.

In preferred embodiments, the device may further include a substrate. In some embodiments, the substrate for the device may include a transparent material, for example, glass, transparent polymer and the like, having light transmittance of greater than about 50%, of greater than about 60%, of greater than about 70%, of greater than about 80%, of greater than about 90%, of greater than about 95%, or of greater than about 99%. The light transmittance, as used herein, may be measured at broad range of light wave lengths, such as from infrared (IR) to ultraviolet (UV) regions. In some embodiments, the light transmittance may be interpreted in the visible light range, particularly when the dopant includes a pigment (dye) or visible light absorbing chemical group which can convert such light energy (h□) into heat, chemical energy or electric energy. In some embodiments, the substrate for the device may include an opaque material, such as a metal, polymers, colored glass, having a light transmittance of less than about 20%, less than about 15%, less than about 10%, less than about 5%, or of about 0%.

In certain exemplary embodiments, the substrate may have a planar, curved, embossed or other surficial shape which may be suitably chosen for the device as described above, however, the shapes or curvature thereof may not be limited to particular examples. Further, the substrate may suitably have a thickness ranging from about 1 μm to about 1 cm, 10 μm to about 10 mm, or preferably from about 10 μm to about 1 mm for the purpose of promoting or improving thermoelectric effect in the device.

In certain exemplary embodiments, the device further includes a conductive layer that is disposed or coated on an inner surface of each substrate, and the conductive layer may be connected to at least a first surface or a second surface of the M-TE lipid layer.

In certain exemplary embodiments, the conductive layer may be disposed or coated in a predetermined area, or at a predetermined distance from each other on the surface of the substrate. As such, density and distribution of the dopant may be determined or adjusted by the layout or positioning of the conductive layer on the substrates. In particular embodiments, the conductive layer may be disposed on the surface of the substrate of about 10% of surface area, of about 20% of surface area, of about 30% of surface area, of about 40% of surface area, of about 50% of surface area, of about 60% of surface area, of about 70% of surface area, of about 80% of surface area, or of about 90% of surface area of the substrate.

Further, the conductive layer may suitably have a thickness less than about 100 μm, less than about 10 μm, less than about 1 μm, less than about 100 nm, less than about 10 nm, or from about 1 nm to about 100 μm.

In certain exemplary embodiments, the device may also include a boundary layer that connect or attach the dopant in the M-TE lipid layer to the conductive layer or to the inner surfaces of the substrates. Alternatively, the boundary layer may be attached to the hydrophilic groups of the lipid-bilayer. For instance, the boundary layer may connect each end of the dopants from both the surfaces of the lipid bilayer, and to the conductive layers (see FIGS. 4A-4B).

In certain embodiments, the boundary layer may be disposed or coated in a predetermined area, or at a predetermined distance from each other on the surface of the M-TE lipid layer, on the surface of the substrate or on the surface of the conductive layer. As such, density and distribution of the dopant may also be determined or adjusted by the layout or positioning of the boundary layer on the substrates. In particular embodiments, the boundary layer may be disposed on the surface of the substrate of about 10% of surface area, of about 20% of surface area, of about 30% of surface area, of about 40% of surface area, of about 50% of surface area, of about 60% of surface area, of about 70% of surface area, of about 80% of surface area, or of about 90% of surface area of the substrate.

Further, the boundary layer may suitably have a thickness less than about 100 μm, less than about 10 μm, less than about 1 μm, less than about 100 nm, less than about 10 nm, or from about 1 nm to about 100 μm.

In certain exemplary embodiments, the boundary layer may be attached to only one surface (either first or a second surface) of the M-TE lipid bilayer. Then, referring to FIG. 5A, the device may also include a conductive solution or an electrolyte filling the spaces between the M-TE lipid bilayer and the conductive layer at the surface where the M-TE lipid bilayer is not connected to the conductive layer via boundary layer.

In some embodiment, the device may include a boundary layer that connects or attaches at least one surface or dopant of the M-TE lipid layer to the substrate. Further, the device may include a non-conductive solution or a buffer solution filling the spaces between the surface the lipid bilayer where the boundary layer is not attached between at least one surface of the M-TE lipid layer and the substrate. In particular, the non-conductive solution can serve as a buffer solution for chemical reactions. For example, the photoactive group or other catalysts as described above can be attached on the dopant and exposed in the buffer solution where the photosensitive chemical reaction may occur in response to the sunlight thereby generating electrons, and thus generated electrons may be transferred to the dopant, thereby causing electric current.

In some embodiments, the device further includes an electric circuit. For instance, the electric circuit may be formed by the conductive layer disposed between the inner surfaces of the substrate. Alternatively, the electric circuit may be connected to the substrates. In some embodiments, the device having an electric circuit may include at least a first and second non-conductive substrate that may be positioned parallel to one another, thereby forming the outer surfaces of the device. A plurality of conductive layers may be positioned adjacent to or disposed on the interior surfaces of the non-conductive layer. The M-TE lipid bilayer may be disposed between and electrically connected to the conductive layers. For example, individual M-TE lipid units may be connected in series to a network of conductive layers. In some embodiments, an electrical conductor may be activated via exposure to a direct current that may be applied to the conductive layer to direct an electron flow in a particular manner or an alternate method such as thermal exposure. Additionally, the application of the direct current may determine the heat flow direction. For example, a potential difference across the first and second conductive layers may cause the electrons to flow through the M-TE lipid bilayer, causing a temperature gradient to develop and may thereby provide both heating and cooling system capabilities. Further, in another embodiment, the device may allow the electric circuit disposed therein to be coupled to a terminal external to the device, thereby allowing the power generated from the device to be utilized by an external circuit or system.

Further, in one aspect of the present invention, a method of manufacturing the device includes: preparing a lipid bilayer; doping the lipid bilayer with a dopant to provide a molecular thermoelectric(M-TE) lipid layer; and disposing the M-TE lipid layer on at least one surface of a substrate. The M-TE lipid layer may be characterized as described above.

In one preferred aspect, the method may further include connecting an electric circuit to the substrate. In particular embodiments, the electric circuit may be formed internal to the device by coupling the plurality of conductive layers to the M-TE lipid bilayer disposed therebetween. In some embodiments, an electrical current can be generated by the conductive layer and the power generated therein may be utilized by an external circuit that may be coupled to the conductive layer of the device. In an alternate embodiment, a direct current may be applied via a conductive layer to the circuit disposed within the device to alter the flow of electrons within the circuit. Altering the flow of electrons may create a temperature gradient and may alter the heat flow of the device. In particular, controlling the flow of electrons thereby creating a thermal gradient may enable the device to have heating and cooling capabilities.

The following examples illustrate the invention and are not intended to limit the same.

### EXAMPLES

### Example 1

### Model System 1 (Folded Trans Membrane Protein M-TE/Lipid System)

In an exemplary embodiment, a model-system may include individual trans-membrane [n/p/n-type]ₙ folded protein units that are embedded within a lipid bi-layer matrix (see FIGS. 6A-6B) Each folded protein may contain two conductive terminals, one at each end, whereby the terminal ends pultrude opposing sides of the lipid bilayer. Two conductive boundary layers, one on each side of the lipid-bilayer, allow a potential difference to be applied across the terminals of the trans-membrane folded protein. This potential difference may cause electron-flow through the M-TE folded units, which in turn causes a temperature gradient to develop across the bilayer. Lipid mobility within the individual leaflets may provide proper in-plane heat dissipation. In particular embodiments, the model system may be used for both heating and cooling applications by reversing polarity. Alternatively, the model system may also work in reverse, that is, electrical power may be generated when opposing lipid leaflets are subject to a thermal gradient.

### Example 2

### Model System 2 (Serial M-TE/Lipid System)

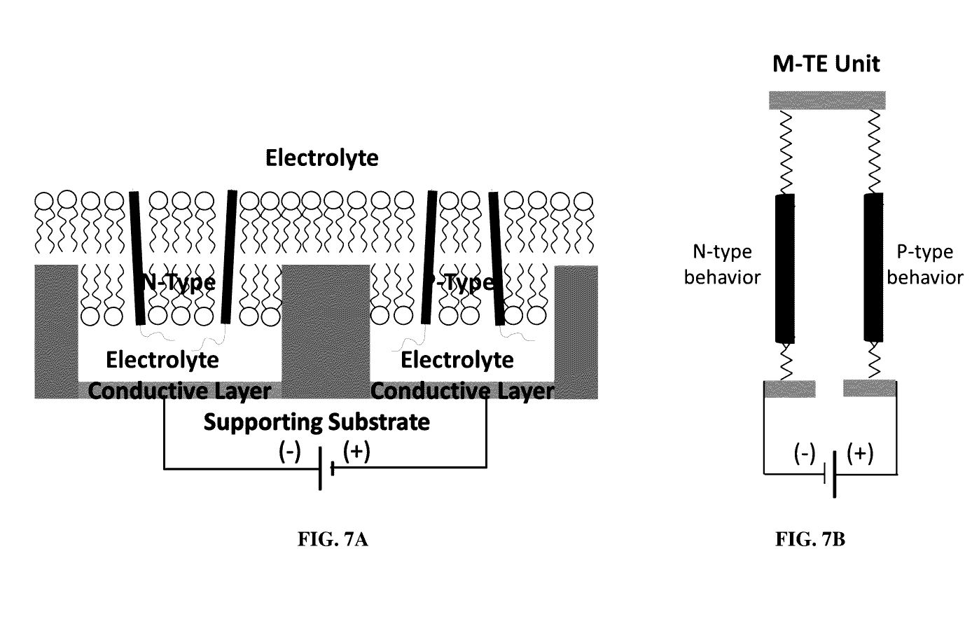

In an exemplary embodiment, a model-system may include individual n-type and p-type molecular dopants, such as alpha helices, that are embedded within confined areas of a lipid bi-layer matrix. Each dopant molecule has a hydrophobic thermoelectric center (n or p-type) that is attached to conductive hydrophilic ends (see FIG. 2A). The dispersion of n-type and p-type dopants may be controlled so that each type is confined within a predetermined distance or predetermined area of the lipid membrane. Individual M-TE units may further be electrically connected to a serial network of conductive layers. The TMP/M-TE system may function as a large TE-module and can be used for both heating and cooling applications by reversing polarity. Alternatively, the M-TE system may also work in reverse, that is, electrical power may be generated when opposing lipid leaflets are subject to a thermal gradient (see FIGS. 7A-7B).

### Example 3

### Solid Finite Element (FE) Model

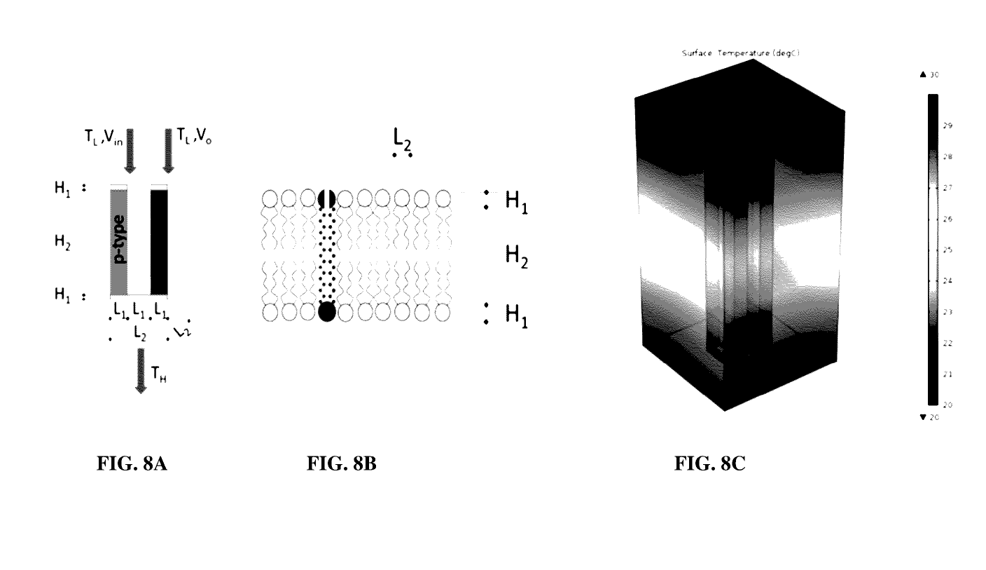

We have previously developed solid FE models of a nanometer-scale M-TE system to estimate the theoretical magnitude of thermoelectric phenomena occurring in lipid bilayer systems. A solid state FE model was developed of an M-TE system with overall dimensions comparable to that of a lipid bilayer system. TE-legs and electrical connections between them were modelled, and their dimensions were kept comparable to those of the hydrophobic tails and hydrophilic heads of a lipid bilayer system respectively (see FIGS. 8A-8C).

Material properties similar to those found in commercially available TE modules (Bismuth Telluride) were assumed. A thermal gradient of 10° C. and 20° C. was applied to the opposing leaflets of the bilayer, and the resulting potential difference was calculated assuming steady state conditions. The M-TE systems was further embedded into a surrounding matrix with thermal conductivity comparable to that of a lipid bilayer system, according to data found in the literature. Dimensions of the matrix were altered in order to represent different M-TE/lipid dispersion-ratios.

The results indicate that the system is capable of generating an electrical potential difference of about 1 mV and 4 mV for a single thermocouple, for a temperature difference of 10° C. and 20° C. respectively. The results also confirm that realistic potential differences can arise when the M-TE unit is subject to thermal gradients found in the natural habitats of many organisms. Potential differences around 50 mV arise when assuming low dimensional M-TE systems, which is consistent with membrane potentials occurring in living cells.

### Example 4

### A Serial M-TE/Lipid System for a Cladding System

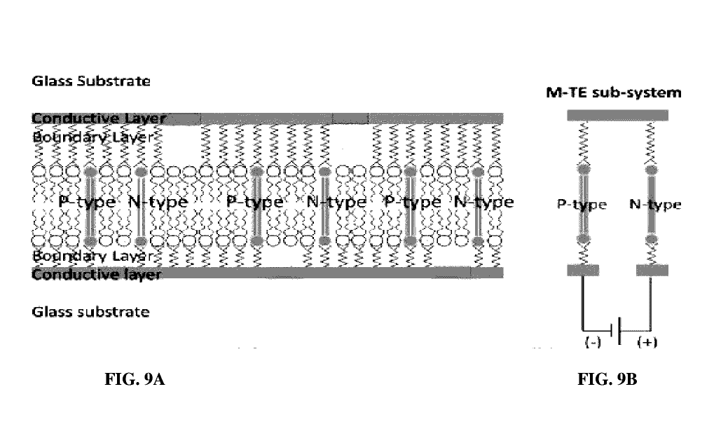

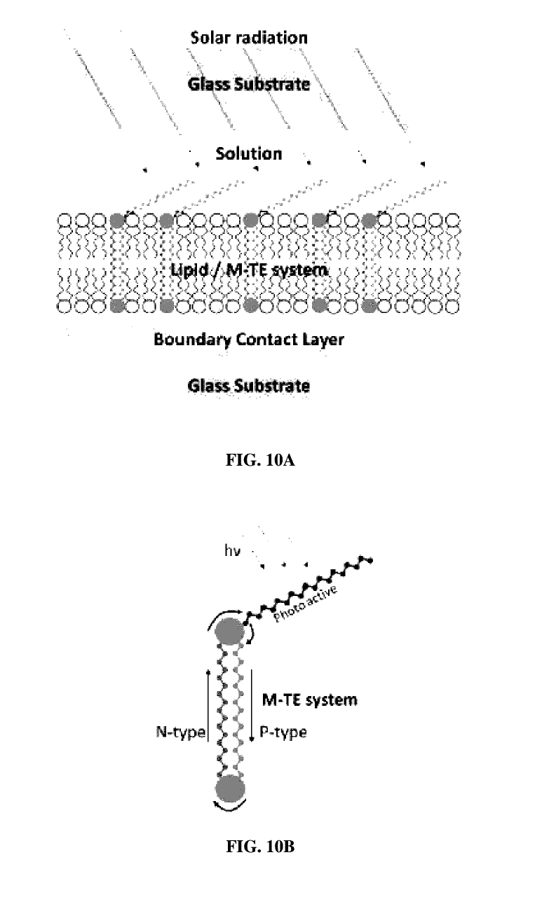

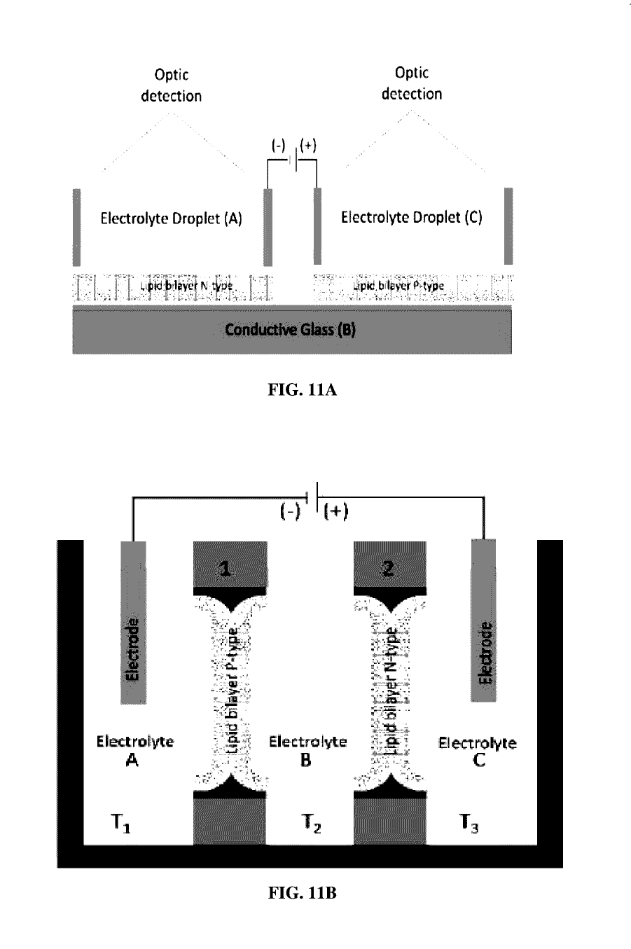

This first model system uses individual n-type and p-type lipid-like molecular units that are embedded within a lipid bi-layer matrix (see FIGS. 9A-9B). Each lipid-like molecule has a hydrophobic thermoelectric center (n or p-type) that is attached to conductive hydrophilic heads (see FIG. 9B). The dispersion of n-type and p-type molecules is controlled so that each type is confined within a predetermined area of a glass surface, for example by using automated dispensing equipment. Individual M-TE units are electrically connected to a serial network of conductive layers deposited on the inner surfaces of the glass panes (see FIG. 9B). This M-TE cladding system functions as a large TE-module and is powered by an external power supply, which can be a window integrated PV system. The system allows for direct thermal control by reversing the current flow, allowing both heating and cooling applications. In addition, this cladding system may also serve as a power source when subject to a thermal gradient.

### Example 5

### Bi-Folded M-TE/Lipid System

The second model system uses individual n/p/n-type (or p/n/p-type) bi-folded lipid-like molecular units that are embedded within a lipid bi-layer matrix (see FIGS. 5A-5B) Each lipid-like molecular bi-fold is attached to conductive hydrophilic heads at its terminals. Two boundary layers, one on each side of the lipid-M-TE system, connect the individual M-TE legs to a conducting layer deposited on the inner surfaces of a double-pane cladding system. A potential difference across the terminals causes electron-flow through the M-TE bi-folded units, causing a temperature gradient across the system (see FIG. 5B). The M-TE cladding system is powered by an external power supply, which can be a window integrated PV system. The system allows for direct thermal control by reversing the current flow (heating or cooling mode). In addition, this cladding system may also serve as a power source when subject to a thermal gradient.

### Example 6

### Solar-powered M-TE/Lipid System

The third model system is solar powered and consists of individual M-TE units that have two hydrophilic heads connected with a pair of thermoelectric legs, whereby one head has a photosensitive dye attached (see FIG. 10A). The lipid-M-TE system is sandwiched between two panes of glass. The lipid M-TE system is supported by the inner pane while a non-conducting solution serves as a buffer between the system and the outer pane of glass. In this cladding system, sunlight enters through the outer glass pane and excites the photosensitive tail of each unit, causing electrons to hop across the hydrophilic head and electron flow across the TE legs (see FIG. 10B). A thermal gradient arises due to the current flow, causing a cooling or heating effect on the inner pane. This system has a very simple construction and operational principle and is solar powered.

### Example 7

### Testing Method

The proposed M-TE system is tested to evaluate dopants candidates.

For example, as shown in FIG. 11A, supported lipid bilayers (SLB) are dispensed on two sections of a conducting indium tin oxide (ITO) substrate, both SLB's are doped with different substances to increase their conductivity using existing doping techniques. Droplets of electrolyte (A and C) are lowered onto the upper leaflet of each lipid-bilayer. A potential difference is applied across the electrode droplets causing a change in temperature. Results are compared with theoretical results and control experiments using virgin SLB.

Further, as shown in FIG. 11B, three compartments (A,B,C) are filled with electrolyte and are separated by two black lipid membranes (BLM). The BLM's are created across Teflon orifices using existing techniques. Both BLM's are doped with different substances to increase their conductivity using existing techniques. A current is applied across electrode A and B and the resulting temperature in compartments A, B, and C is measured and compared with theoretical results and control experiments. Both experiments will also be run in reverse: reservoirs are kept at different temperatures and the resulting potential difference is measured.

### Example 8

### Measuring Thermoelectric Effects in M-TE Systems

Examples of the following experiments can demonstrate the working principle of the exemplary lipid-based TMP/M-TE mechanism. The proposed experiments mandate that a temperature gradient is created across a lipid membrane systems (or a parts thereof), and that the subsequent change in cross-membrane voltage is measured. In reverse, application of a voltage difference can also induce temperature changes that can be detected, for example by detecting fluidity changes in the opposing lipid leaflets. In particular, in-vitro studies can be conducted on the thermoelectric effects occurring in selected trans-membrane proteins using (a) planar patch clamp techniques, and (b) traditional patch clamp techniques for whole cell recording, and (c) supported lipid bilayer (SLB) in combination with patch clamp techniques to study selected trans-membrane proteins.

A high-throughput planar patch clamp technique can be used for initial screening of candidate organisms and TMP dopants, followed by lower-throughput patch clamp techniques for detail-oriented experiments.

(1) Planar Patch-Clamp Screening of TMP/M-TE Activity

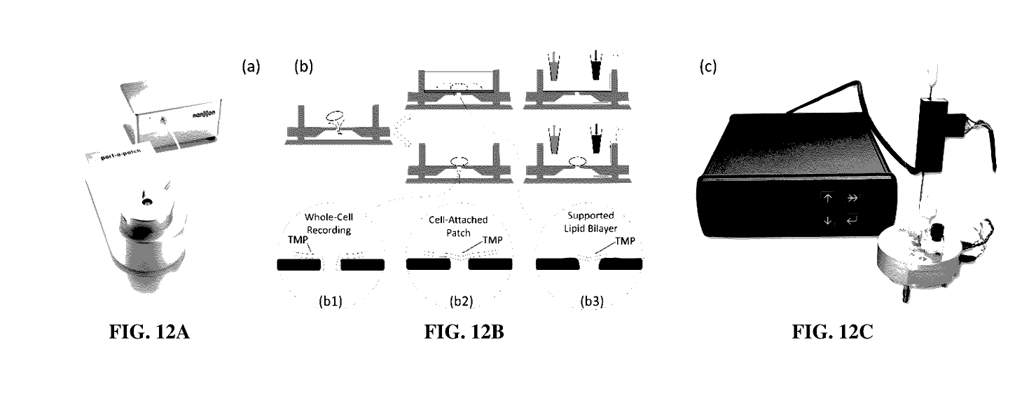

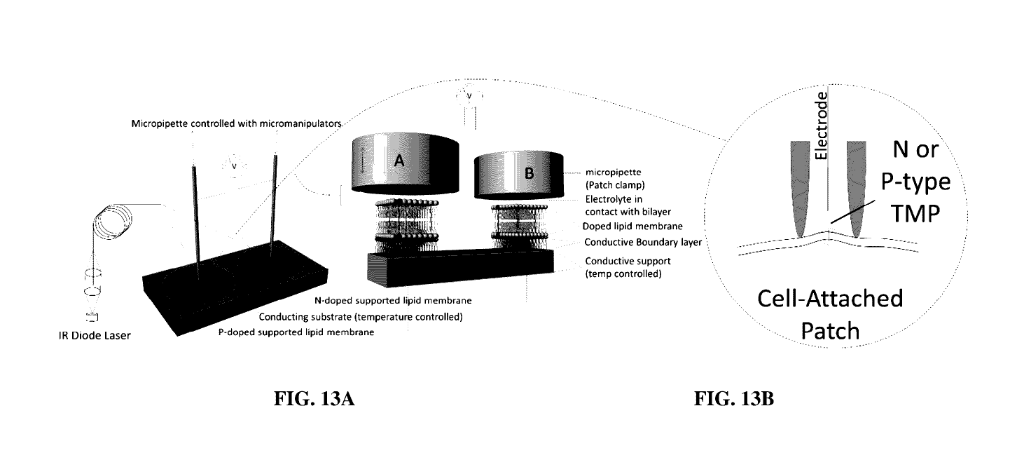

This experimental method is designed to test M-TE effects according to model-system 1 of Example 1 (see FIGS. 12A-12C). A commercially available Planar Patch-Clamp device can be used in conjunction with a commercially available thermal controller (see FIGS. 12A and 12C). Intact cells (native cells or liposomes) are submerged within an electrolyte and drawn into a micro-fabricated orifice by slight suction in the lower chamber of the device until a Giga Ω-seal is attained between the orifice and cell membrane (see FIG. 12A). Reagents can be added to the individual upper and lower compartments, which allows for perfusion of electrolyte solutions of both chambers without compromising the Giga Ω-seal. An external thermal device is used to control the incoming fluid that the cell sees as well as the fluid in the recording manifold independently (see FIG. 12B). Electrophysiological properties of selected trans-membrane-proteins can be measured upon thermal cycling. Different recording techniques will be used.

a. The cell-attached patch technique can be used to assess the M-TE properties of single trans-membrane proteins (see FIG. 12B(b1)). Temperature in upper and lower chambers may be cycled to induce thermal gradients across the lipid membrane, and the resulting potential difference will be recorded.

b. The whole-cell recording technique can be used to test M-TE properties of multiple trans-membrane proteins distributed throughout the entire cell surface (see FIG. 12B(b2)). This techniques allows for internal perfusion of the cell, and thus provides more temperature control.

c. The supported lipid bilayer technique can be used for to test the M-TE functionality of TMPs (see FIG. 12B(b3)). The temperature of the extra-cellular fluid as well as the recording manifold can be controlled independently. The potential-difference upon temperature change is recorded. Both slow and rapid temperature jumps may be tested to identify possible time sensitive properties of the proposed M-TE mechanism. Results are compared with theoretical results and control-experiments using lipid-only-liposomes and/or supported lipid bilayers.

(2) Supported Lipid Bilayers/Patch Clamp Screening of Dopants: This experimental method is designed to test M-TE effects according to model system 2 of Example 2 (see FIGS. 13A-13B). Supported lipid bilayers (SLB) are constructed on two sections of a conducting indium tin oxide (ITO) substrate using existing. Both SLB's are doped with different substances to increase their conductivity using existing doping techniques.

Micropipettes (A and B) are lowered onto the upper leaflet of each lipid-bilayer using a micromanipulator under optical control until a Giga-ohm seal is accomplished. A temperature difference is applied across the electrode droplets causing a change potential. Real time detection of temperature gradients will be accomplished by using temperature sensitive fluorescent dyes. Both slow and rapid temperature jumps will be tested to identify possible time-sensitive properties of the proposed TMP/M-TE mechanism. Slow temperature changes can be accomplished, for example with a Peltier-device to cool/heat the substrates supporting opposing leaflets. Rapid temperature changes can be accomplished with infrared diode laser irradiation, as described elsewhere. Results are compared with theoretical results and control-experiments using virgin SLB.

(3) Supported Lipid Bilayers/Patch Clamp Screening of TMP

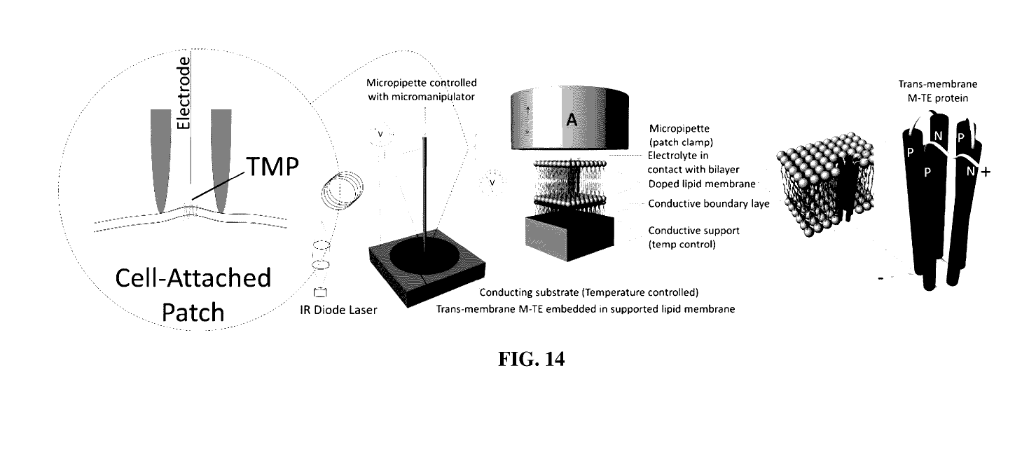

This experimental method is designed to test M-TE effects according to model-system 1 of Example 1 (see FIG. 14). Supported lipid bilayers (SLB) are fabricated onto a conducting indium tin oxide (ITO) substrate using existing techniques. The M-TE may be either (i) derived from liposomes which incorporate trans-membrane proteins using existing techniques described elsewhere, or (ii) the SLB is created directly from natural organisms.

The cell-attached patch-clamp technique can be used to assess the M-TE properties of single SLB trans-membrane proteins. A micropipette is lowered onto the upper leaflet of the lipid-bilayer using a micromanipulator under optical control until Giga Ω-seal is attained between the pipette and cell membrane. A temperature difference may be applied across the electrolyte and the supporting substrate, and the potential difference across the lipid bilayer may be measured. Real time detection of temperature gradients may be accomplished by using temperature sensitive fluorescent dyes, as described elsewhere. Both slow and rapid temperature jumps can be tested to identify possible time-sensitive properties of the proposed TMP/M-TE mechanism. Slow temperature changes can be accomplished, for example with a Peltier-device to cool/heat the substrates supporting opposing leaflets. Rapid temperature changes can be accomplished with infrared diode laser irradiation, as described elsewhere. Results are compared with theoretical results and control-experiments using virgin SLB. This experimental procedure provides an additional path to detect M-TE functionality according to model system 1, and can therefore also be used as control to experiment type 1 as described above (or vice versa).

### Example 9

### Design of TMP/M-TE Devices

The n-type and p-type dopants of prototypical M-TE systems can be evaluated and integrated systems and devices. For example, advanced modeling techniques may be used to provide TMP/M-TE systems at various scales.

(1) Heat Transfer TMP/Lipid Matrix: Molecular Dynamics

TMP interactions with the surrounding lipid bilayer matrix may determine the heat-transfer-dynamics of the proposed lipid-embedded TMP/M-TE system. Molecular Dynamics modelling tools may be suitably used to study the heat conduction characteristics of lipid bilayer systems.

(2) Finite Element (FE) Method

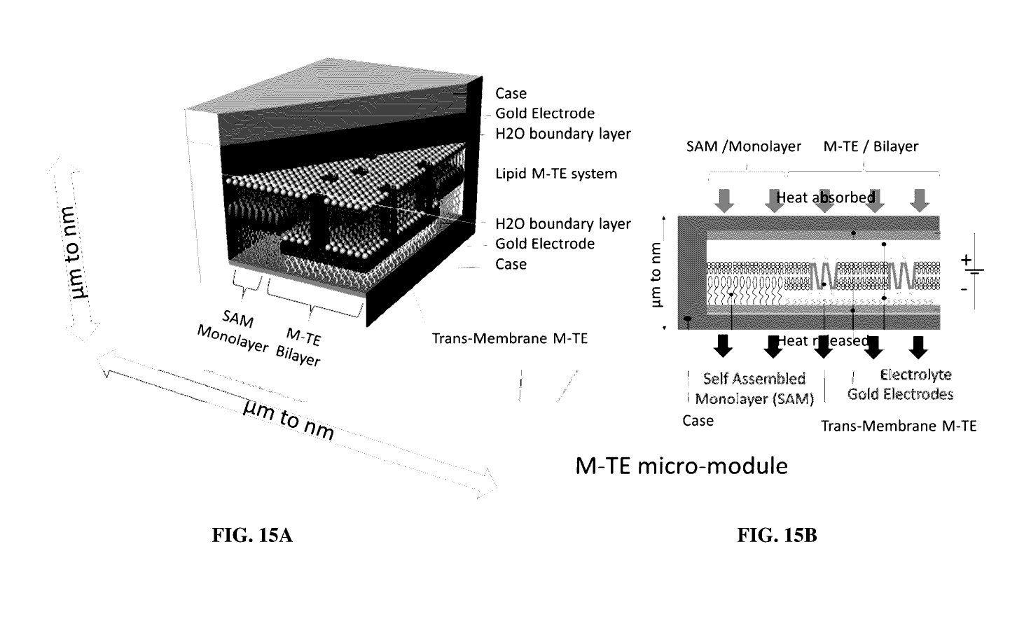

The economic viability of M-TE systems can be determined for commercial applications. FIGS. 15A-15B depict a schematic of our proposed design for a micro-scale M-TE module. In the proposed design, the lipid membrane is firmly attached to a solid support while maintaining aqueous electrolyte regions between the membrane leaflets and its supports, providing space for the pultruding sections of the M-TE trans-membrane proteins. The sides of the lipid bilayer are isolated from the module's casing using anchoring molecules at the module boundary. This boundary isolates and stabilizes the bilayer section of the module while leaving the upper leaflet continuous. Packing molecules are used under the M-TE active portion of the bilayer. The top and bottom aqueous electrolyte regions are in contact with a gold layer deposited onto the casing, which consist of an inorganic material. Layer fabrication techniques are described in several references on discrete membrane arrays. The encapsulated design may shelter the fragile lipid system from external environmental conditions, which may result in long lasting and predictable performance. The proposed system can either act as a cooling device (voltage applied) or as a power source (thermal gradient applied).

In addition, FE system-level (solid) models can be developed for the prototypical M-TE device depicted in FIGS. 15A-15B. An optimization study can be performed to determine optimal system parameters. Variables include thickness of the various layers, their physical properties, lipid/trans-membrane M-TE doping ratio's, and geometric design. Realistic boundary conditions and constraints can be used. Modeling results will be aimed at uncovering those system-designs that can offer high thermoelectric figure-of-merit, which may be the primary evaluation criteria. A numerical framework for assessing the technical and commercial viability of the lipid-like M-TE module may be obtained, result can also be used for cost analysis.

(3) Micro-scale M-TE Module Integrated into a Vacuum Cladding System

In addition to micro-device modeling, new vacuum cladding systems may be designed to be integrated with the micro-scale M-TE modules to provide thermoelectric zero-energy cladding system. FIG. 16A depicts a commercially available vacuum cladding system using micro-pillars to space apart two panes of glass. A vacuum is created between the glass panes to minimize conductive and convective heat flow while low emissivity (Low-E) coatings are used to optimize radiation heat transfer between the two panes. FIG. 16B depicts our alternative design whereby micro-scale M-TE modules serve as micro-pillars, and whereby a photovoltaic system is integrated into the outer pane of glass to power the micro-scale M-TE modules.

FE system-level (solid) models can be developed for the prototypical vacuum cladding system, and optimization studies can be further performed to determine optimal system parameters. Design variables include thickness of the various glass layers, physical properties such as emissivity and degree of vacuum, as well as geometric design constraints. Realistic boundary conditions and constraints may be used and different climate types may be considered. Modeling results are aimed at uncovering those system-designs that can offer high coefficient of performance, which may be primary evaluation criteria. Cost estimates may also be used to calculate the estimated payback period of the proposed cladding system. The system can be used as a power generating and/or thermal control device.

### Other Embodiments

From the foregoing description, it will be apparent that variations and modifications may be made to the invention described herein to adopt it to various usages and conditions. Such embodiments are also within the scope of the following claims.

The recitation of a listing of elements in any definition of a variable herein includes definitions of that variable as any single element or combination (or subcombination) of listed elements. The recitation of an embodiment herein includes that embodiment as any single embodiment or in combination with any other embodiments or portions thereof.

All patents and publications mentioned in this specification are herein incorporated by reference to the same extent as if each independent patent and publication was specifically and individually indicated to be incorporated by reference.

What is claimed is:

1. A molecular thermoelectric (M-TE) lipid layer, comprising:
a lipid layer; and
a dopant,
wherein the dopant is a p-type dopant, a n-type dopant or hybrids thereof.

2. The molecular thermoelectric (M-TE) lipid layer of claim 1, wherein the lipid layer is assembled in vitro.

3. The molecular thermoelectric (M-TE) lipid layer of claim 1, wherein the lipid layer is in a form of a monolayer, a bilayer, or mixtures thereof.

4. The molecular thermoelectric (M-TE) lipid layer of claim 1, wherein the lipid layer is formed using a lipid selected from the group consisting of: a fatty acid, a phospholipid, a glycolipid and mixtures thereof.

5. The molecular thermoelectric (M-TE) lipid layer of claim 1, wherein the dopant is lipid-compatible.

6. The molecular thermoelectric (M-TE) lipid layer of claim 1, wherein the dopant is a lipid, a peptide, oligonucleotides, a synthetic compound or mixtures thereof.

7. The molecular thermoelectric (M-TE) lipid layer of claim 1, wherein the dopant comprises archaeal macrocyclic di-ether lipids or archaeal tetra-ether lipids.

8. The molecular thermoelectric (M-TE) lipid layer of claim 1, wherein the dopant is a transmembrane peptide or a fragment thereof.

9. The molecular thermoelectric (M-TE) lipid layer of claim 8, wherein the transmembrane peptide comprises at least one transmembrane domain that is embedded in the lipid layer.

10. The molecular thermoelectric (M-TE) lipid layer of claim 8, wherein one or more of the transmembrane domains are connected via a linker.

11. The molecular thermoelectric (M-TE) lipid layer of claim 9, wherein the transmembrane peptide further comprises a photoactive group which is not embedded in the lipid layer.

12. The molecular thermoelectric (M-TE) lipid layer of claim 8, wherein the transmembrane peptide is a fragment obtained from a pigment protein which is modified.

13. The molecular thermoelectric (M-TE) lipid layer of claim 8, wherein the transmembrane peptide comprises a fragment obtained from an ion channel which is modified.

14. The molecular thermoelectric (M-TE) lipid layer of claim 8, wherein the transmembrane peptide comprises a fragment obtained from a modified rhodopsin.

15. The molecular thermoelectric (M-TE) lipid layer of claim 1, wherein the dopant is poly(dA)-poly(dT) oligonucleotides, poly(dC)-poly(dG) oligonucleotides or mixtures thereof.

14. The molecular thermoelectric (M-TE) lipid layer of claim 1, wherein the dopant comprises a photoactive group which is not embedded in the lipid layer.

15. The molecular thermoelectric (M-TE) lipid layer of claim 1, wherein the lipid layer is formed in multiple layers.

16. A molecular thermoelectric (M-TE) device, comprising:
the molecular thermoelectric (M-TE) lipid layer of claim 1; and
an electrical conductor.

17. The molecular thermoelectric (M-TE) device of claim 16, wherein the molecular thermoelectric (M-TE) device is a medical/biologic device, an optical device, a microarray, or a cladding system.

18. A device, comprising:
a molecular thermoelectric (M-TE) lipid layer comprising a lipid layer and a dopant; and
substrates,
wherein the M-TE lipid layer is arranged between the substrates.

19. The device of claim 18, wherein the dopant is lipid compatible.

20. The device of claim 18, wherein the dopant is an n-type dopant, a p-type dopant, or a hybrid thereof.

21. The device of claim 18, wherein the dopant is a lipid, a peptide, oligonucleotides, a synthetic compound, or a mixture thereof.

22. The device of claim 18, wherein the dopant comprises a photoactive group.

23. The device of claim 18, further comprising a conductive layer disposed on an interior surface of at least one of the substrates.

24. The device of claim 18, further comprising a boundary layer arranged adjacent to the conductive layer.

25. The device of claim 24, wherein the boundary layer is configured to connect the dopant and the conductive layer.

26. The device of claim 18, further comprising an electrolyte.

27. The device of claim 18, further comprising a non-conductive solution.

28. The device of claim 18, further comprising an electric circuit disposed between the substrates, wherein the substrates are positioned parallel to one another.
